(19) United States
(12) Patent Application Publication
(10) Pub. No.: US 2013/0252432 A1
(43) Pub. Date: Sep. 26, 2013

(54) PATTERNING METHOD

(71) Applicants: Masaru Nakamura, Okayama (JP); Takashi Kawaguchi, Okayama (JP); Yoshinori Ikagawa, Okayama (JP); Chisato Nagahata, Okayama (JP)

(72) Inventors: Masaru Nakamura, Okayama (JP); Takashi Kawaguchi, Okayama (JP); Yoshinori Ikagawa, Okayama (JP); Chisato Nagahata, Okayama (JP)

(73) Assignee: TAZMO CO., LTD., Okayama (JP)

(21) Appl. No.: 13/992,932

(22) PCT Filed: Dec. 16, 2011
(86) PCT No.: PCT/JP2011/079142

§ 371 Date: Jun. 10, 2013

(30) Foreign Application Priority Data
Dec. 17, 2010 (JP) 2010-281994

(51) Int. Cl. H01L 21/306

(52) U.S. Cl. CPC H01L 21/306
USPC 438/706

(57) ABSTRACT

Provided is a patterning method that can greatly reduce process costs and environmental load. The patterning method includes: a film forming step of forming a functional film (2) on a substrate (1) ; and an etching step of irradiating the substrate with vacuum ultraviolet light (12) from above a mask (4) that is placed on the functional film (2) and has an arbitrarily-defined opening (4A) so as to dry etch the functional film (2) positioned below the opening (4A). The dry etching step can be carried out in an atmosphere containing oxygen. For example, dry air can be used as process gas. In addition, N₂ may be supplied as an inert gas to the substrate (1) placed in the atmosphere.

### TECHNICAL FIELD

The present invention relates to a patterning method in which a predetermined pattern is formed on a functional film formed on a surface of a substrate.

### BACKGROUND ART

Conventionally, the technology in which a predetermined pattern is formed by dry etching a film formed on the surface of a substrate has been known (see Patent Literature 1, for example). Dry etching, because not accompanied by a wet developing step, is simple and widely used for the patterning purpose.

Typical kinds of a dry etching method include a method in which a material is exposed to reactant gas (reactive gas etching), and reactive ion etching in which etching is carried out by ionizing and radically treating gas by plasma.

### CITATION LIST

### Patent Literature

Patent Literature 1: Japanese Patent Laid-Open Publication No. 2005-116639

### SUMMARY OF INVENTION

### Technical Problem

The conventional dry etching treatment requires to supply, as process gas, inert gas such as Xe, Kr, Ar, Ne, and He, or chlorine based and fluorine based reactive gas, and has problems that process costs are high and environmental load also becomes large.

In view of the foregoing problems, an object of the present invention is to provide a patterning method that can greatly reduce process costs and environmental load.

### Solution to Problem

In order to achieve the foregoing object, a patterning method of the present invention includes: a film forming step of forming a functional film on a substrate; and an etching step of irradiating the functional film with vacuum ultraviolet light from above a mask having an arbitrarily-defined opening, the mask being placed on the functional film so as to dry etch the functional film that is positioned below the opening.

In the patterning method of the present invention, since vacuum ultraviolet light is used for irradiation, the dry etching step can be carried out in an atmosphere containing oxygen. For example, dry air may be used as process gas. In addition, N₂ may be supplied as an inert gas to the substrate placed in the atmosphere. Thus, without using special process gas, process costs and environmental load can be greatly reduced.

The patterning method of the present invention also includes a substrate treating step of modifying the surface of the substrate by irradiating the surface of the substrate with ultraviolet light before the film forming step. According to this step, the adherence between the surface of the substrate and a functional film to be formed in the subsequent step is improved, and the uniformity of the thickness of the film is achieved. Moreover, it is possible to carry out modification as well as oxidization cleaning of: the contaminant of an organic substance, remaining on the surface of various materials; and oil oozing from a material itself, by vacuum ultraviolet light and active oxygen.

In addition, the patterning method of the present invention can obtain an n layered functional film on which a pattern is formed in the same pattern by alternatively and repeatedly carrying out the film forming step and the etching step for each layer of a different functional film laminated in n layers (n is an integer equal to or larger than two).

It is to be noted an example of the functional film includes a conductive film in which conductive polymer contains a metal particle. In this case, it becomes possible to remove the metal particle remaining in an etched area by injecting carbon dioxide gas to the surface of the substrate after the etching step of the conductive film. Other examples of the functional film include a hole injection layer, an anode buffer layer on the conductive film, a p-type semiconductor layer on a buffer layer.

### Advantageous Effects of Invention

According to the patterning method of the present invention, process costs and environmental load can be greatly reduced.

### BRIEF DESCRIPTION OF THE DRAWINGS

FIGS. 1A to 1D are views (sectional views) that illustrate a patterning method according to the present invention;

FIGS. 2A and 2B are views (sectional views) that illustrate the patterning method according to the present invention; and

FIGS. 3A to 3C are views (sectional views) that illustrates the patterning method according to the present invention.

### DESCRIPTION OF EMBODIMENTS

Hereinafter, the patterning method according to the present invention will be described based on the preferred embodiments shown in the accompanying drawings.

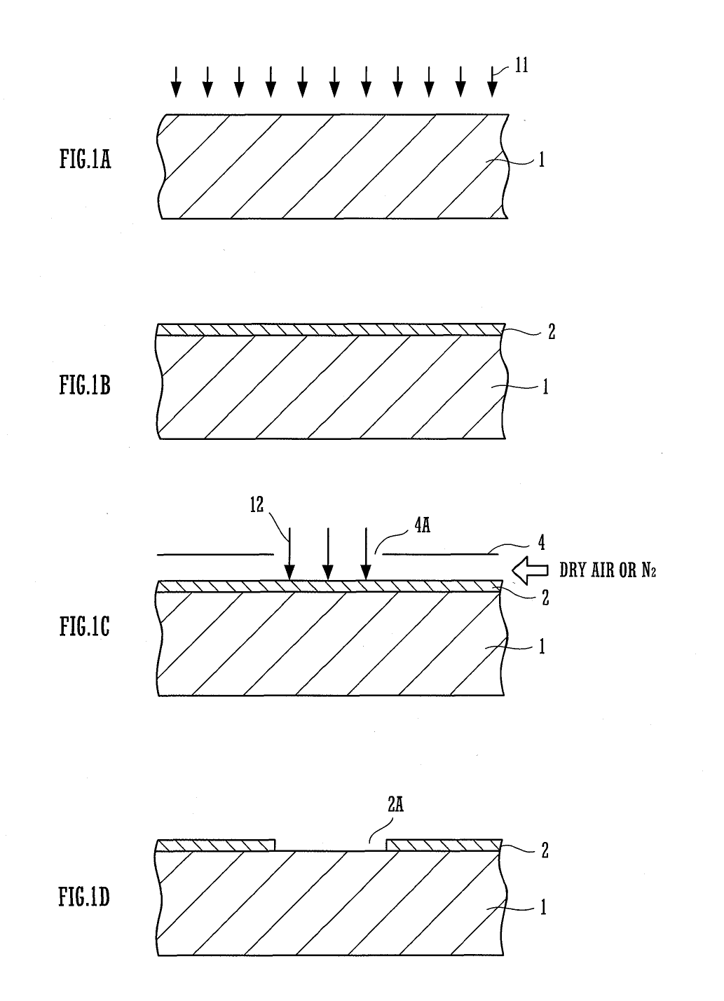

FIGS. 1A to 1D, FIGS. 2A and 2B, and FIGS. 3A to 3C are sectional views for describing the patterning method.

As shown in FIG. 1D, the patterning method of the present invention is a method in which a predetermined pattern is formed on a functional film formed on the surface of a substrate 1 by dry etching.

The patterning method according to the present embodiments includes: a substrate treating step [1] of modifying the surface of the substrate by irradiating the surface of the substrate with ultraviolet light; a film forming step [2] of forming a functional film on the substrate; and an etching step [3] of irradiating the functional film with ultraviolet light in a vacuum ultraviolet light area from above a mask having an arbitrarily-defined opening, the mask being arranged on the functional film, so as to dry-etch the functional film that is positioned below the opening.

### [1] Substrate Treating Step

To begin with, as shown in FIG. 1A, the surface of the substrate 1 is irradiated with ultraviolet light 11. The substrate 1 is made of a material of which the surface modification is advanced by irradiation of ultraviolet light 11. Specifically, a glass substrate and a resin substrate are used preferably. Examples of the resin substrate include a PEN film (biaxially stretched polyethylene 2, 6-naphthalate) and a PET film (biaxially stretched polyethylene terephthalate) that are useful as a resin substrate for a solar cell and an organic EL element.

In the substrate treating step, an excimer lamp (manufactured by Quark Technology Co., Ltd) can be used preferably as an ultraviolet light source. The excimer lamp emits vacuum ultraviolet light with a wavelength of 172 nm. It should be noted not only the excimer lamp but also a low pressure mercury lamp, a high pressure mercury lamp, and a ultraviolet. LED can be used as the ultraviolet light source used in the substrate treating step.

The following description is given with respect to the modification principal of the surface of the substrate by ultraviolet light irradiation by way of a case in which a resin substrate is used as the substrate 1 and vacuum ultraviolet light is used as the ultraviolet light 11 as an example.

When the surface of the substrate is irradiated with the vacuum ultraviolet light, most of the main chains and side chains of surface molecules are cut off by high energy, and a hydrogen atom included in the material is separated from the surface. This hydrogen atom is combined with active oxygen (OH radical oxygen and the like, for example) generated from oxygen in the atmosphere by the ultraviolet light to form an acyl group (COH), a hydroxyl group (OH), a carboxyl group (COOH) and the like on the surface. Accordingly, the physical properties and the chemical properties of the surface of the substrate (improvement of the smooth property and the hydrophilic property, etc.) are modified. As a result, the adherence between the surface of the substrate and a functional film to be formed in the subsequent step is improved, and the uniformity of the thickness of the film is achieved. In addition, it is possible to carry out modification as well as oxidization cleaning of: the contaminant of an organic substance, remaining on the surface of various materials; and oil oozing from a material itself, by vacuum ultraviolet light and active oxygen.

### [2] Film Forming Step

Subsequently, as shown in FIG. 1B, a functional film 2 is formed on the substrate 1. Examples of the functional film include a conductive film, a hole injection layer, an anode buffer layer on the conductive film, a p-type semiconductor layer on a buffer layer. Examples of the material for forming a conductive film can include Ag containing polymer, a carbon nanotube, an Ag nanoparticle, and ITO.

The functional film 2 can be formed by being dried after the material of the functional film 2 is wet applied onto the substrate 1. Examples of a wet application method can include a slit coat method, a spin coat method, a spray coat method, a bar coat method, and screen printing. Drying can be carried out by combining air-drying with heating with a hot plate, an oven, an infrared heater, and the like.

### [3] Etching Step

Subsequently, as shown in FIG. 1C, a mask 4 having an arbitrarily-defined opening 4A is placed on the functional film 2, and is irradiated with the vacuum ultraviolet light 12. Due to this, the functional film 2 is dry etched by setting a part of the functional film 2 positioned below the opening 4A as an etched region 2A. As a result, a predetermined pattern corresponding to the placement of the opening 4A of the mask 4 is formed on the functional film 2 (see FIG. 1D).

As the vacuum ultraviolet light 12 used in the etching step, vacuum ultraviolet light emitted from an excimer lamp with a wavelength of 172 nm can be used preferably.

The etching step can be carried out in an atmosphere containing oxygen. For example, dry air can be used as process gas. In addition, N₂ may be supplied as an inert gas to the substrate 1 placed in the atmosphere. That is, since special process gas is not used, process costs and environmental load are reduced greatly.

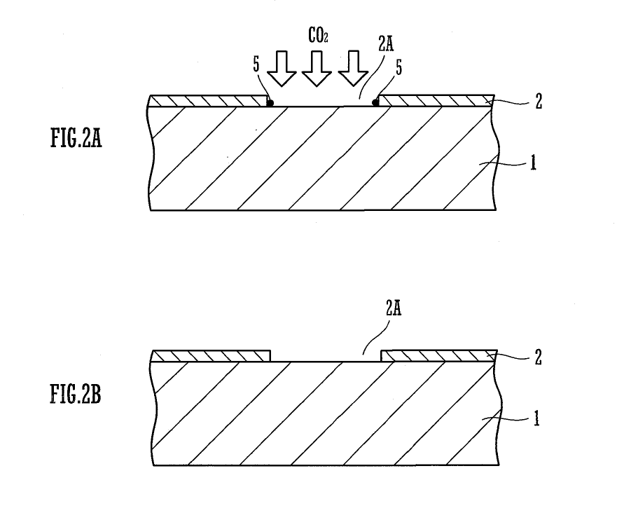

In a case in which a metal particle, such as Ag, is included in the functional film 2, after the etching step, as shown in FIG. 2A, the metal particle 5 may remain in the etched area 2A of the surface of the substrate, which raises concerns about influence on an aspect ratio. Thus, as shown in FIG. 2B, the metal particle that remains in the etched area may be blown away to be removed by injecting carbon dioxide gas to the surface of the substrate after the etching step.

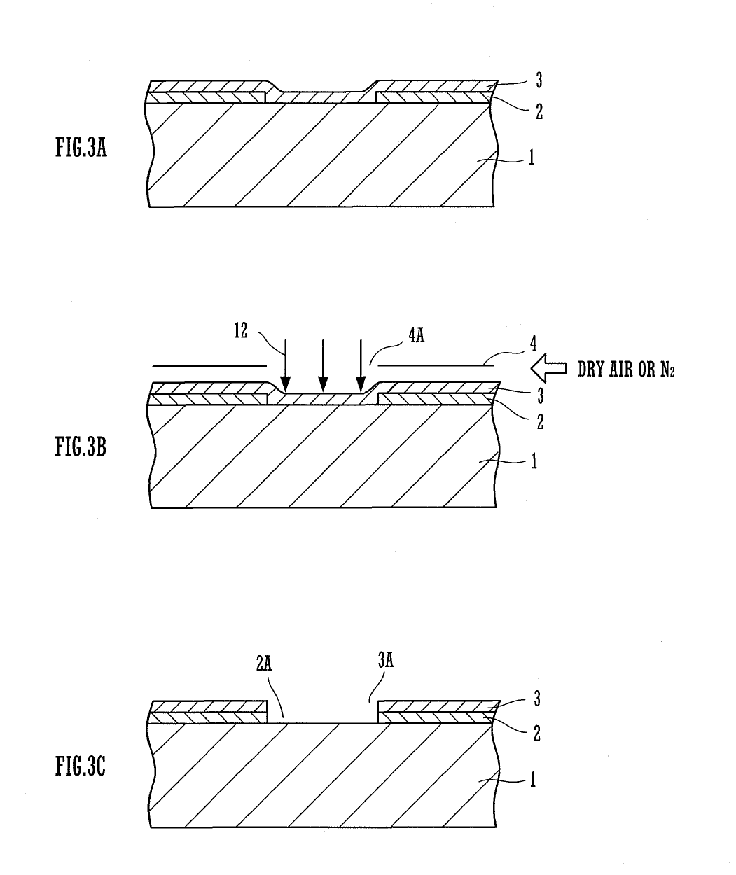

Moreover, as shown in FIGS. 3A to 3C, a different functional film 3 is formed on the functional film 2 on which the predetermined pattern is formed as described above, in the same manner as the above stated film forming step (see FIG. 3A), and this upper layered functional film 3 is further dry etched in the same manner as the above stated etching step (see FIG. 3B), so that the patterning of the upper layered functional film 3 can be carried out in the pattern the same as the lower layered functional film 2. Examples of the lower layered functional film 2 can include Ag-containing polymer and ITO and an example of the upper layered functional film 3 can include a hole injection layer. Such combination of the functional films is preferably used for the manufacture of an organic EL element. It is to be noted that the functional film 3 can be stably formed if the lower layered functional film 2 is irradiated with ultraviolet light before applying the upper layered functional film 3 and the hardness of the functional film 2 is increased.

Furthermore, by repeating the similar film forming step and etching step, a different functional film can be obtained, the functional film being laminated in n layers (n is an integer equal to or larger than two) and formed in the same pattern.

The etching possibility of the functional film was examined using the patterning method according to the present invention. The experiment was conducted in the following manner.

### [Experiment 1]

Three samples of a transparent conductive film applied onto a glass substrate to about 50 to 70 nm were obtained. The three samples are set as embodiments 1 to 3, respectively. Then, these samples were irradiated with the vacuum ultraviolet light with a wavelength of 172 nm by varying the irradiation time, and the variations of the thickness of the transparent conductive film were examined. The results are shown in Table 1.

TABLE 1

| | |
|---|---|
| Vacuum ultraviolet | Conductive film |
| light | thickness [nm] |

| | Irradiation time | Before | After |
|---|---|---|---|
| Sample | [sec] | irradiation | irradiation |
| Embodiment 1 | 30 | 55.8 | 24 |
| Embodiment 2 | 60 | 70.4 | 35.1 |
| Embodiment 3 | 300 | 63.9 | 29.4 |

As shown in Table 1, the thickness of the transparent conductive film is decreased significantly by vacuum ultraviolet light irradiation, so that it was confirmed that dry etching was carried out. Although the wet etching in place of ultraviolet light irradiation was also examined, the transparent conductive film is solidified with dilute nitric acid, rare hydrofluoric acid, and dilute hydrochloric acid and ideal etching could not be carried out.

Moreover, based on the results shown in Table 1, the etched depth was 31.8 nm in the sample of Embodiment 1, 35.3 nm in the sample of Embodiment 2, and 34.5 nm in the sample of Embodiment 3. The etched depth is saturated in 30 to 60 seconds, which indicates that even if the irradiation time is lengthened, it turns out that the etching rates are nearly unchanged.

Subsequently, the patterning of the functional film was actually carried out using the patterning method according to the present invention. The experiment was conducted in the following manner.

### [Experiment 2]

### <Film Formation Conditions>

A non-alkali glass substrate was used as a substrate, applied with an Ag content polymer conductive film in 80 nm thickness by the slit coat method, and dried by air for five minutes, dried on a hot plate at 60 degrees ° C. for five minutes, and further dried in an oven at 120 degrees ° C. for five minutes. It should be noted that an infrared heater may be used in place of the oven.

### <Etching Conditions>

A mask that has a predetermined opening was placed on the substrate is placed and nitrogen gas was supplied to the surface of the substrate by a flow rate of 20 L/min. An excimer lamp (with a wavelength of 172 nm) was used as a ultraviolet light source. The distance (the irradiation range) from the light source to the surface of the substrate was set to 4 mm, the irradiation intensity was set to 40 mW/cm², and the irradiation time was set to 300 seconds.

By carrying out the patterning under such conditions, it is estimated that the patterning was carried out on the conductive film in the predetermined pattern according to the results of Experiment 1.

The above described embodiments are to be considered in all respects as illustrative and not restrictive. The scope of the present invention is defined not by above described embodiments but by the claims. Further, the scope of the present invention is intended to include all modifications that come within the meaning and scope of the claims and any equivalents thereof.

### REFERENCE SIGNS LIST

1 Substrate
2, 3 Functional film
2A, 3A Etched area
4 Mask
5 Metal particle
11 Ultraviolet light
12 Vacuum ultraviolet light

1. A patterning method comprising:
a film forming step of forming a functional film on a substrate; and
an etching step of irradiating the functional film with vacuum ultraviolet light from above a mask that is placed on the functional film and has an arbitrarily-defined opening so as to dry etch the functional film that is positioned below the opening.

2. The patterning method according to claim 1, further comprising:
a substrate processing step of modifying a surface of the substrate by irradiating the surface of the substrate with ultraviolet light before the film forming step.

3. The patterning method according to claim 1, wherein the film forming step and the etching step are alternatively and repeatedly carried out for each layer of a different functional film laminated in n layers (n is an integer equal to or larger than 2.)

4. The patterning method according to claim 1, wherein the functional film is a conductive film in which conductive polymer contains a metal particle.

5. The patterning method according to claim 4, further comprising:
a step of removing the metal particle remaining in an etched area by injecting carbon dioxide gas onto the surface of the substrate after the etching step.

6. The patterning method according to claim 1, wherein the functional film is a hole injection layer.

7. The patterning method according to claim 1, wherein the functional film is an anode buffer layer on a conductive film.

8. The patterning method according to claim 1, wherein the functional film is a p-type semiconductor layer on a buffer layer.

9. The patterning method according to claim 2, wherein the functional film is a conductive film in which conductive polymer contains a metal particle.

10. The patterning method according to claim 9, further comprising:
a step of removing the metal particle remaining in an etched area by injecting carbon dioxide gas onto the surface of the substrate after the etching step.

11. The patterning method according to claim 2, wherein the functional film is a hole injection layer.

12. The patterning method according to claim 2, wherein the functional film is an anode buffer layer on a conductive film.

13. The patterning method according to claim 2, wherein the functional film is a p-type semiconductor layer on a buffer layer.
